(19) United States
(12) Patent Application Publication
(10) Pub. No.: US 2004/0029552 A1
(43) Pub. Date: Feb. 12, 2004

(54) Image transmitting method, image transmitter, and memory product

(75) Inventors: Atsushi Miki, Kato (JP); Shuji Kimura, Kato (JP); Keiji Fujiwara, Kato (JP); Satoshi Fukui, Kato (JP); Kiyoshi Chinzei, Kato (JP); Mieko Nakano, Kato (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 10/630,802

(22) Filed: Jul. 31, 2003

(30) Foreign Application Priority Data
Aug. 8, 2002 (JP) 2002-231758

(51) Int. Cl. H04B 1/06; H05K 11/00

(52) U.S. Cl. 455/344

(57) ABSTRACT

It is determined whether or not a connection is established between the communication section of an image transmitter and a mobile phone. If it is determined that the connection is established, a request command is transmitted to the mobile phone to obtain the model information of the mobile phone. When the mobile phone receives the request command, it reads the model information from an internal memory, and transmits the model information to the image transmitter. When the image transmitter obtains the model information in response to the request for the model information, it reads conversion information corresponding to the obtained model information with reference to a conversion table. Then, the image transmitter converts the image data stored in a storage unit, based on the read conversion information, and transmits the converted image data to the mobile phone of the image transmitter through the communication section.

### BACKGROUND OF THE INVENTION

1. Field of the Invention

The present invention relates to an image transmitting method and an image transmitter, for storing image data captured by an image capturing unit in a storage unit, reading the stored image data and then transmitting the image data from a communication section to a mobile phone having a display section, and also relates to a computer program and a memory product, for realizing the functions of the image transmitter. The present invention relates particularly to an image transmitting method in which image data obtained from an image capturing unit of an image transmitter, such as a scanner, is converted according to the characteristics of each model of mobile phone of each manufacturer, and then transmitted to the mobile phone.

2. Description of the Prior Art

In recent years, with an increase in mobile phones having a liquid crystal display with a large display area, a technique for displaying an image captured by external sources as a standby screen on the liquid crystal display is widely used. Moreover, with the spread of digital cameras, a technique to connect a digital camera and a mobile phone with a cable, transmit image data taken by the digital camera to the mobile phone and display the image data as a standby screen on the display section of the mobile phone is known.

By the way, various types of mobile phones have been released from each manufacturer, and their characteristics such as resolution, color number and display area vary depending on each model. Therefore, when image data taken by a digital camera is directly transmitted, some models may have problems, for example, the image data is displayed out of the screen or colors are not reproduced accurately. Hence, image data is transmitted after converting the image data according to the characteristics of each model so as to match a variety of mobile phones.

As the above-described technique, image transmitters disclosed in Japanese Laid-Open Patent Publications No. 2001-238037 and No. 2001-298717 have been known. FIG. 1 is a flow chart showing the procedure to be performed by a conventional image transmitter. First, the image transmitter displays a screen for selecting a model of mobile phone on the display section (step S201). More specifically, a list of the model names of mobile phones of respective manufacturers is displayed. Subsequently, the image transmitter determines whether or not one model is selected (step S202). If no model is selected (NO in step S202), the image transmitter moves to step S201 and repeats the process.

If one model is selected (YES in step S202), the information about the selected model is stored, and a guide screen to take a picture or capture an image is further displayed on the display section (step S203). When an image capturing signal is inputted by an operation of a user, a picture is taken or an image is captured (step S204), and the obtained image data is stored in the storage unit. Then, referring to a memory in which the model data about each mobile phone is stored, the process of enlarging or reducing the image data is performed according to the model data corresponding to the model (step S205). Finally, the enlarged or reduced image data is transmitted to the mobile phone (step S206).

However, the image transmitters disclosed in Japanese Laid-Open Patent Publications No. 2001-238037 and No. 2001-298717 require their user to perform the task of selecting one model from a plurality of models, and this is a troublesome task for the user. Moreover, since it is necessary to provide the image transmitters with a display section for the selection of a model, there is the problem of an increase in the costs.

Furthermore, since new model of mobile phone is released one after another, the model data stored in the memory, etc. for conversion of image data becomes out of date soon, and, when a new model is released, there arises the problem that the image data is not converted properly.

### BRIEF SUMMARY OF THE INVENTION

The present invention has been made with the aim of solving the above problems. An object of the present invention is to provide an image transmitting method which causes an image transmitter to request a mobile phone to obtain information on a model, which will be referred to as model information hereinafter when a communication is established between the image transmitter such as a scanner and the mobile phone, and thereby capable of easily converting image data and transmitting the converted image data to the mobile phone without requiring a user to select the model of his/her mobile phone, and also to provide the image transmitter and a memory product storing a computer program for realizing the functions of the image transmitter.

Another object of the present invention is to provide an image transmitter which, if model information obtained from the mobile phone or conversion information corresponding to the model information is not present, obtains the conversion information corresponding to the model information from external sources. Therefore, even when a new mobile phone is released, the image transmitter can convert image data according to the new mobile phone.

An image transmitting method according to the present invention is an image transmitting method for storing image data captured by an image capturing unit of an image transmitter in a storage unit, reading the stored image data and transmitting the read image data from a communication section of the image transmitter to a mobile phone having a display section, and characterized by comprising the steps of determining whether or not a connection is established between the communication section and the mobile phone; requesting the mobile phone to obtain model information of the mobile phone if it is determined that the connection is established; reading conversion information corresponding to the obtained model information with reference to a conversion table that stores conversion information, which is used to convert captured image data into image data according to characteristics of a model, which will be referred to as model characteristics hereinafter, in association with each model information, when the model information is obtained from the mobile phone in response to the request for the model information; converting the image data stored in the storage unit, based on the read conversion information; and transmitting the converted image data to the mobile phone through the communication section.

An image transmitter according to the present invention is an image transmitter for storing image data captured by an image capturing unit in a storage unit, reading the stored image data and transmitting the read image data from a communication section to a mobile phone having a display section, and characterized by comprising: means for determining whether or not a connection is established between the communication section and the mobile phone; means for requesting the mobile phone to obtain model information of the mobile phone if it is determined that the connection is established;, means for reading conversion information corresponding to the obtained model information with reference to a conversion table that stores conversion information, which is used to convert captured image data into image data according to model characteristics, in association with each information; means for converting the image data stored in the storage unit, based on the read conversion information, when the model information is obtained from the mobile phone in response to the request for the model information; and transmitting means for transmitting the converted image data to the mobile phone through the communication section.

An image transmitter according to the present invention is characterized by further comprising: means for obtaining conversion information corresponding to the obtained model information from external sources, if the obtained model information or conversion information corresponding to the model information is not present in the conversion table; and means for storing the conversion information corresponding to the model information obtained by the obtaining means in the conversion table.

An image transmitter according to the present invention is characterized by further comprising: means for storing a communication address of a server computer which is connected to the mobile phone through a network and stores the conversion information corresponding to the model information; means for outputting a connection request command for the server computer, the stored communication address and the obtained model information to the mobile phone, if the obtained model information or conversion information corresponding to the model information is not present in the conversion table; means for requesting the mobile phone to obtain the conversion information corresponding to the model information of the mobile phone, which is distributed to the mobile phone from the server computer; and means for storing the obtained conversion information corresponding to the mobile phone in the conversion table in association with the model information.

An image transmitter according to the present invention is characterized by further comprising means for providing information indicating the absence of corresponding conversion information, if the obtained model information or conversion information corresponding to the model information is not present in the conversion table.

An image transmitter according to the present invention is characterized by further comprising a protocol table storing a protocol for a transmission of image data between the communication section and mobile phone, in association with each model information, wherein the transmitting means is designed to read a protocol corresponding to the obtained model information from the protocol table and transmit the image data converted according to the read protocol to the mobile phone through the communication section.

A computer readable memory product according to the present invention is a memory product storing a computer program for storing image data captured by an image capturing unit of an image transmitter in a storage unit, reading the stored image data and transmitting the read image data from a communication section of the image transmitter to a mobile phone having a display section, and characterized in that the stored computer program comprises the steps of causing a computer to determine whether or not a connection is established between the communication section and the mobile phone; causing the computer to request the mobile phone to obtain model information of the mobile phone if it is determined that the connection is established; causing the computer to read conversion information corresponding to the obtained model information with reference to a conversion table that stores conversion information, which is used to convert captured image data into image data according to model characteristics, in association with each information, when the model information is obtained from the mobile phone in response to the request for the model information; causing the computer to convert the image data stored in the storage unit, based on the read conversion information; and causing the computer to transmit the converted image data to the mobile phone through the communication section.

In the present invention, image data captured by the image capturing unit such as a CCD (Charge Coupled Device) or a line image sensor is stored in the storage unit. Besides, there is prepared a conversion table that stores conversion information, which is used to convert captured image data into image data according to model characteristics, in association with each model information. The conversion information is information about display size, color number, image format, etc. The image transmitter and a mobile phone are connected with a cable, infrared communication, etc., and then it is determined whether a connection is established between the communication section of the image transmitter and the mobile phone.

If it is determined that the connection is established, a request command to obtain the model information of the mobile phone is transmitted to the mobile phone so as to request the mobile phone to obtain the model information. When the mobile phone receives this request command, it reads the model information from the internal memory and transmits the model information to the image transmitter. When the image transmitter obtains the model information in response to the request for the model information, it reads the conversion information corresponding to the obtained model information with reference to the conversion table.

Then, the image transmitter converts the image data stored in the storage unit, based on the read conversion information, and transmits the converted image data to the mobile phone through the communication section. It is thus possible to easily transmit the image data without requiring the user to enter the model information of his/her mobile phone. Moreover, since the display screen for selection can be omitted if necessary, it is possible to provide a low-cost image transmitter. In other words, it is often the case that general users do not correctly remember the model names of mobile phones they purchased and the model names of mobile phones of third parties. However, with the present invention, it is possible to capture images by simple capturing and connecting operations.

In the present invention, if the obtained model information or conversion information corresponding to the model information is not present in the conversion table, the conversion information corresponding to the model information is obtained from external sources. For example, the image transmitter is connected to a computer capable of accessing a Web server so as to receive a distribution of the conversion information from the Web server via the computer.

As another example, the communication address such as the URL (Uniform Resource Locator) of a server computer which is connected to the mobile phone through a network and stores the conversion information corresponding to the model information is stored. Then, if the obtained model information or conversion information corresponding to the model information is not present in the conversion table, a connection request command for the server computer, the stored communication address and the obtained model information are outputted to the mobile phone.

The sever computer distributes the conversion information corresponding to the model information to the mobile phone. The image transmitter outputs to the mobile phone a request command to obtain the distributed conversion information corresponding to the model information of the mobile phone so as to request the mobile phone to obtain the conversion information. In this manner, the obtained conversion information for the new mobile phone is further stored in the conversion table in association with the model information. Thus, even when a new model is released, it is possible to transmit appropriate image data to the new mobile phone without making the image transmitter out of date.

The present invention prepares a protocol table that stores a protocol for a transmission of image data between the communication section and the mobile phone. In other words, since the protocols, such as the destination memory and transmission timing of image data, vary according to the specifications of mobile phones, there is a need to convert the protocols in addition to the conversion of image data. Therefore, when transmitting image data, a protocol corresponding to the obtained model information is read from the protocol table, and then the image data converted according to the read protocol is transmitted to the mobile phone through the communication section of the image transmitter. In this manner, it is possible to appropriately transmit image data to various types of mobile phones.

The above and further objects and features of the invention will more fully be apparent from the following detailed description with accompanying drawings.

### BRIEF DESCRIPTION OF THE SEVERAL VIEWS OF THE DRAWINGS

FIG. 1 is a flow chart showing the procedure to be performed by a conventional image transmitter;

FIG. 2 is a schematic view showing the outline of the present invention;

FIG. 3 is a block diagram showing the hardware structure of a handy scanner of the present invention;

FIG. 4 is an explanatory view showing the record layout of a conversion table;

FIG. 5 is an explanatory view showing the record layout of a protocol table;

FIGS. 6A through 6C are a flow chart showing the procedure of transmission process;

FIGS. 7A and 7B are a flow chart showing the procedure for obtaining new model information, etc.;

FIG. 8 is an explanatory view showing a screen image displayed on a display section;

FIG. 9 is a schematic view showing the outline of the handy scanner, etc. of the second embodiment;

FIG. 10 is a flow chart showing the procedure for obtaining new model information, etc.; and

FIG. 11 is a schematic view showing the outline of the handy scanner, etc. of the third embodiment.

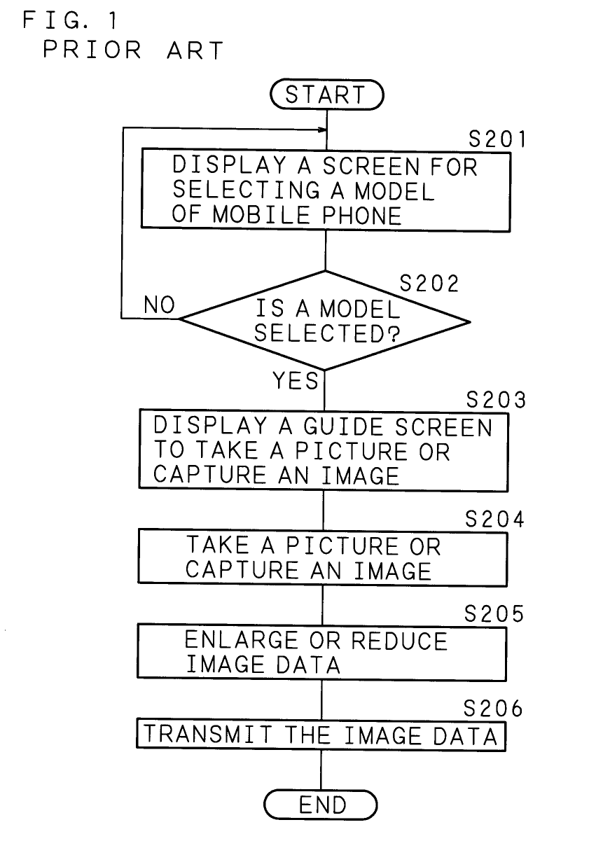

### DESCRIPTION OF THE PREFERRED EMBODIMENTS

First Embodiment

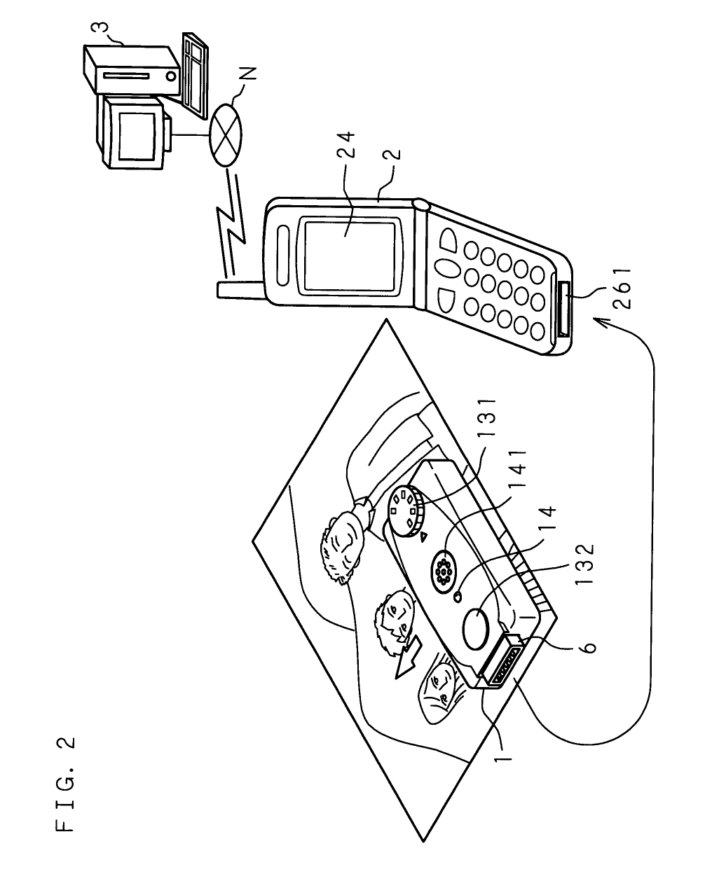

FIG. 2 is a schematic view showing the outline of the present invention. In FIG. 2, the numeral 1 is an image transmitter according to the present invention, and, for example, a handy scanner, a digital still camera, a digital video camera or the like is used. Note that the following explanation is given based on the assumption that the image transmitter 1 is a handy scanner 1. The handy scanner 1 has on its front surface a mode selection button 131 for selecting a scan mode, a transmission mode, etc.; and a scanning/transmission start button 132 which is used to start scanning and transmit image data that is captured into a mobile phone 2.

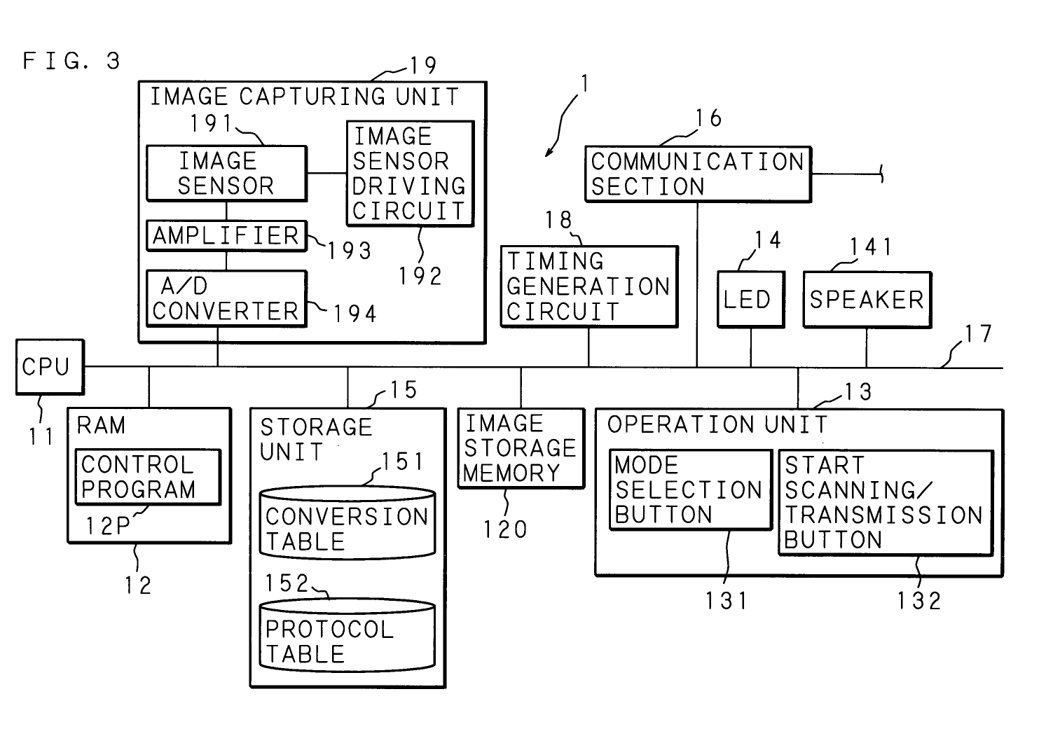

An image sensor (see FIG. 3) 191 constituting an image capturing unit 19 (see FIG. 3) is placed to appear on the rear surface of the handy scanner 1. After positioning the mode selection button 131 to the scan mode, when the scanning/transmission start button 132 is pressed, the image sensor is activated to capture an image. To transmit the captured image data to the mobile phone 2, a communication section 16 protruding from one end of the handy scanner 1 is fitted into an external device I/F 261 provided in the mobile phone 2.

Then, by positioning the mode selection button 131 to the transmission mode and pressing the scanning/transmission start button 132, the image data is transmitted and displayed on a display section 24 of the mobile phone 2 after obtaining later-described model information and converting the image data. Note that, in this embodiment, although the mobile phone 2 and the handy scanner 1 are physically connected through the communication section 16, the present invention is not necessarily limited to this, and may transmit and receive information by using communicating means such as infrared communication or Blue Tooth. The numeral 14 is an LED (Light Emitting Diode), and 141 is a speaker. They emit light or output sound when executing various operations.

N is a communication network such as the Internet, and the mobile phone 2 can transmit and receive necessary information from a server computer 3 (hereinafter referred to as the “WWW server 3”) through the communication network N by HTTP (Hypertext Transfer Protocol). With the present invention, it is particularly possible to receive distribution of the model information, conversion information and protocol data about the mobile phone 2 from the WWW server 3.

FIG. 3 is a block diagram showing the hardware structure of the handy scanner 1 according to the present invention. The handy scanner 1 is connected through a bus 17 to a CPU (Central Processing Unit) 11, image capturing unit 19, operation unit 13, storage unit 15, timing generation circuit 18, RAM (Random Access memory) 12, image storage memory 120, communication section 16, LED 14, speaker 141, etc.

The CPU 11 is connected to each of the above-mentioned hardware devices of the handy scanner 1 through the bus 17. The CPU 11 controls these devices, and also executes various software functions, according to a control program 12P stored in the RAM 12. For the control program 12P, the following software processes are written in programming languages such as C language and Java (registered trademark). The image capturing unit 19 is composed of an image sensor (line image sensor) 191, an image sensor driving circuit 192, an amplifier 193, and an AID converter 194.

By pressing the scanning/transmission start button 132 of the operation unit 13, a drive signal is outputted from the image sensor driving circuit 192 to the image sensor 191, and scanning of an original image is started. Analog image signals of the original image formed by an optical system of the image sensor 191 are amplified by the amplifier 193, and then converted into digital image data by the A/D converter 194. The converted image data is stored in the image storage memory 120 such as a DRAM (Dynamic Random Access Memory). The timing generation circuit 18 outputs timing signals for the operations of hardware devices such as the image capturing unit 19 and the communication section 16. The communication section 16 is an interface for performing transmission and receiving of commands, image data, etc. between the communication section 16 and the mobile phone 2. The communication section 16 and the external device I/F 261 of the mobile phone 2 are connected with a cable. Note that the transmission and receiving of information may be performed by using the Blue Tooth as described above. In this case, in order to communicate with the mobile phone 2 by using 2.45 GHz radio wave, a wireless aerial part, a RF part, a base band part, a quartz oscillator, etc. (not shown) need to be mounted in the communication section 16. Alternatively, the information may be transmitted and received to/from the mobile phone 2 by infrared communication. In this case, a signal transmitting and receiving part (not shown) for infrared communication needs to be mounted in the communication section 16.

As the communicating means, for example, as in this embodiment, the LED 14, speaker 141, etc. are used, and light is emitted or sound is outputted when performing various operations. As described above, the operation unit 13 is composed of the mode selection button 131 and the scanning/transmission start button 132. For the mode selection button 131, “power off”, and three modes, namely, “scan mode small”, “scan mode middle” “scan mode large” (which are represented as a “scan mode” in some cases) are prepared according to a scan area. In addition, a “transmission mode” to the mobile phone 2 is prepared. One mode is selected by setting the mode selection button 131 in the form of a dial to a predetermined position. When the “scan mode small” is selected, the image sensor driving circuit 192 sets the image capturing area of the image sensor 191 to a predetermined area (with a scan width of 3 cm, for example). Then, by taking the pressing of the scanning/transmission start button 132 as a trigger, the image data captured by the image sensor 191 is stored in the image storage memory 120.

Similarly, when the “scan mode middle” is selected, the image sensor driving circuit 192 sets the image capturing area of the image sensor 191 to a predetermined area (with a scan width of, for example, 5 cm, or 9 cm for the scan mode large). Then, by taking the pressing of the scanning/transmission start button 132 as a trigger, the image data captured by the image sensor 191 is stored in the image storage memory 120. The RAM 12 is made of an SRAM (Static Random Access Memory), a flush memory or the like, and stores temporary data generated during the execution of software. The storage unit 15 stores a model information conversion table 151 and a protocol table 152. The contents of the tables are explained below.

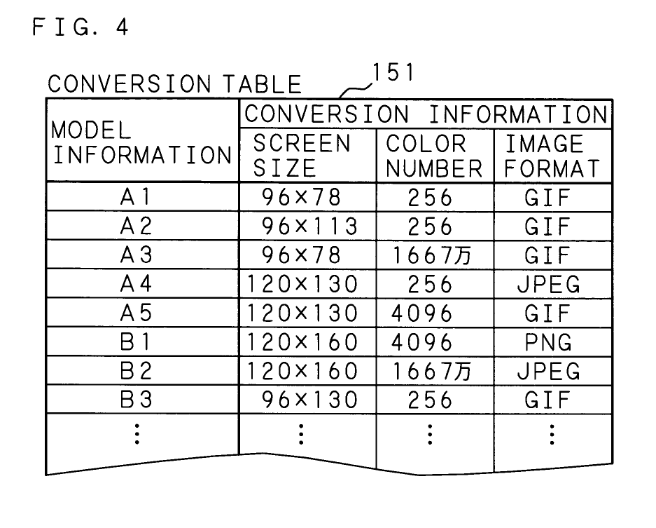

FIG. 4 is an explanatory view showing the record layout of the conversion table 151. As shown in FIG. 4, conversion information is stored in association with the model information of each mobile phone 2 of each manufacturer. The conversion information shows the model characteristics, and is used in converting an image captured by the image capturing unit 19 so as to appropriately display the image on the display section 24 of each mobile phone 2. In the model information field, the model information (the code number, etc.) of each mobile phone 2 of each manufacturer is stored. In the screen size field, the number of pixels in each of the vertical direction and horizontal direction of the display section 24 of each mobile phone 2 is stored, and, in the color number field, the number of displayable colors is stored. Additionally, in the image format field, the image format used by each mobile phone 2 is stored. When the CPU 11 obtains the model information, it reads the image data stored in the image storage memory 120 and a screen size corresponding to the model information, and then performs image processing to enlarge or reduce the image.

Moreover, the CPU 11 performs image processing in respect of the number of colors so as to have a number of colors corresponding to the model information, and further converts the image into a corresponding image format. Since the size of the image data captured by the image capturing unit 19 varies depending on an area to be scanned, the enlargement or reducing process is performed according to the size. The number of colors captured by the image capturing unit 19 is full color (16,670,000 colors), and the image is converted into a 256-color or 4096-color image according to a need. Furthermore, the image format of the image data captured by the image capturing unit 19 is a bitmap or JPEG (Joint Photographic Experts Group), and the CPU 11 converts the image data into GIF (Graphic Interface Format) or PNG (Portable Network Graphics) format if necessary. Note that it is possible to update the contents of the conversion table 151 by a later-described method.

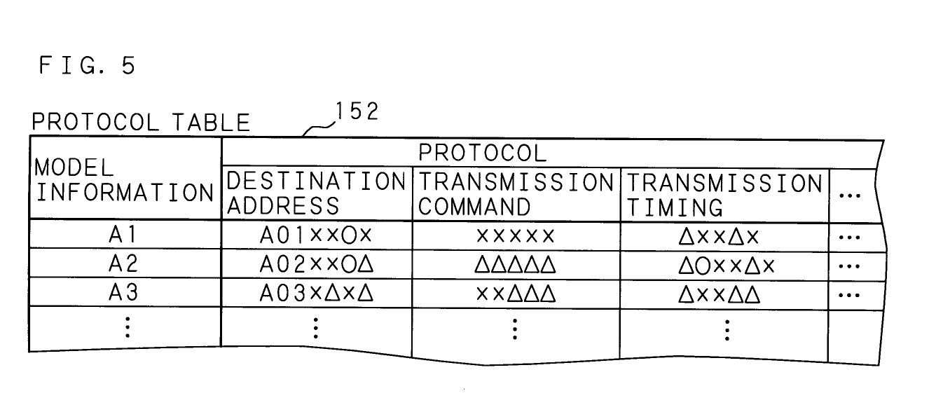

FIG. 5 is an explanatory view showing the record layout of the protocol table 152. As shown in FIG. 5, a protocol for transmitting and receiving information between the handy scanner 1 and the mobile phone 2 is stored in association with the model information. In the destination address field, there is stored the address of a location where the image data to be transmitted to the mobile phone 2 is to be stored. The destination address is stored for each model because a type of the mobile phone 2 stores the transmitted image data in a special folder, but another type stores the transmitted image data in a storage area for the phone number, mail address, etc.

In the transmission command field and the transmission timing field, rules for data communications between the mobile phone 2 and the handy scanner 1, such as the command name and command outputting timing to transmit the data, are stored for each model. When the CPU 11 obtains the model information, it refers to the protocol table 152 and then transmits/receives information according to the protocol of the corresponding model.

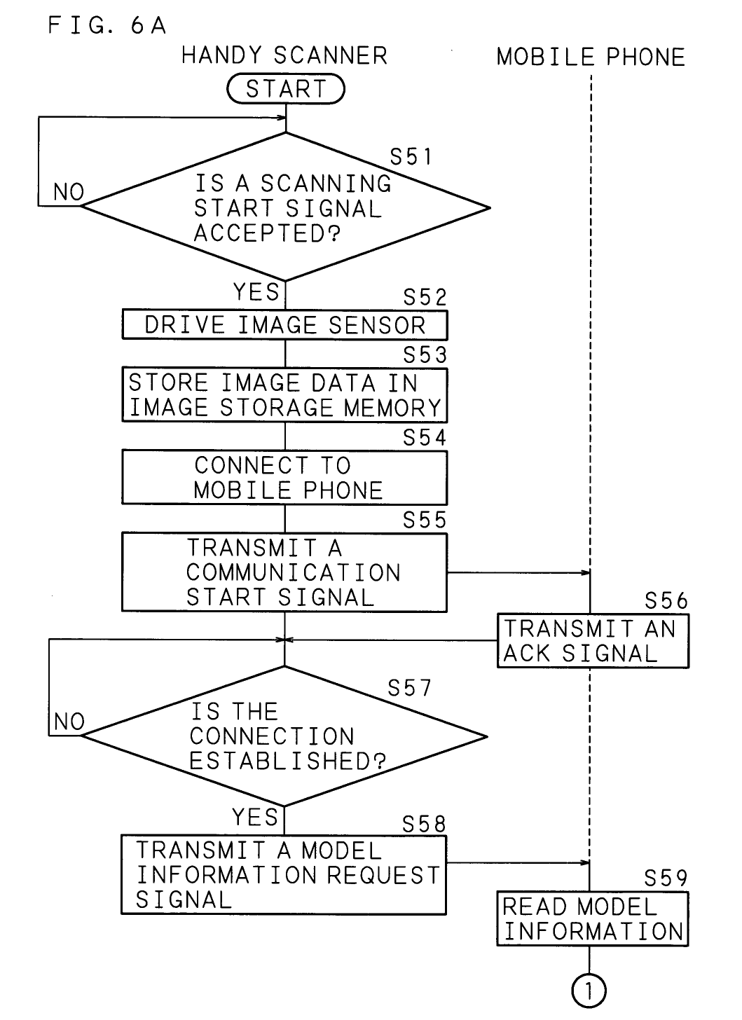

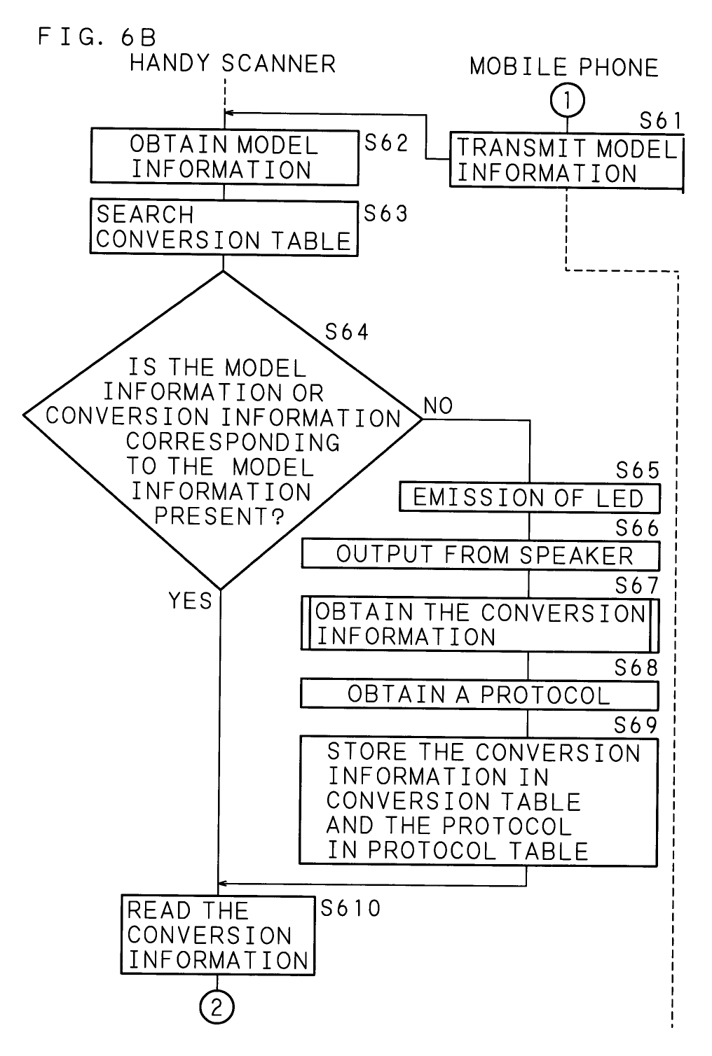

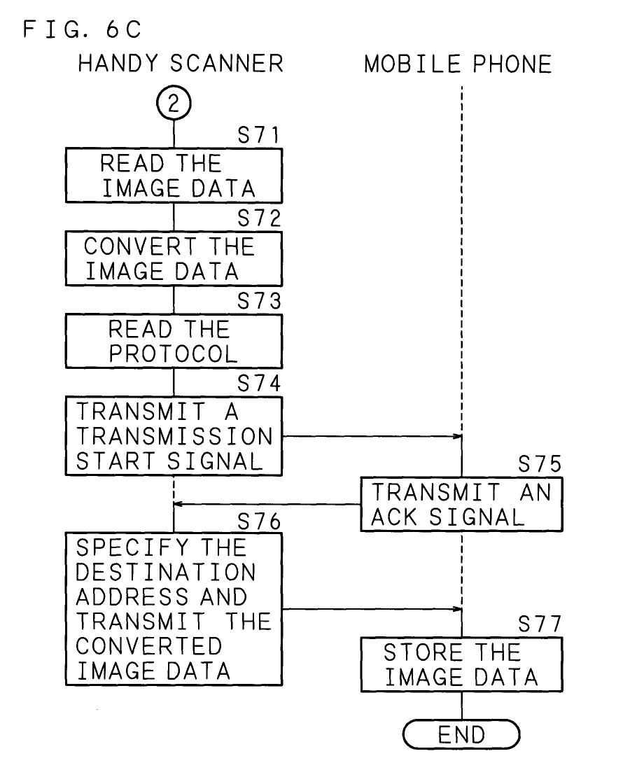

Referring to the flow chart, the following description will explain the procedure of transmission process of the present invention in the above-described structure. FIGS. 6A through 6C are a flow chart showing the procedure of transmission process. To capture an image, the user dials the mode selection button 131 to the “scan mode”, and presses the scanning/transmission start button 132. In this case, a scanning start signal is outputted to the CPU 11. The CPU 11 determines whether the scanning start signal is accepted or not (step S51). If the scanning start signal is not accepted (NO in step S51), the CPU 11 waits until the scanning start signal is accepted. On the other hand, if the scanning/transmission start button 132 is pressed under the “scan mode” and the scanning start signal is accepted (YES in step S51), the CPU 11 drives the image sensor 191 (step S52) to capture the image. The captured image data is stored in the image storage memory 120 together with information such as the information about image data size and date information (step S53).

Subsequently, the user fits the communication section 16 of the handy scanner 1 into the external device I/F 261 of the mobile phone 2 to establish a connection (step S54). In order to request the mobile phone 2 to start communication, the CPU 11 transmits a communication start signal (step S55). When a controller (not shown) of the mobile phone 2 receives the communication start signal, it transmits an ACK signal to the handy scanner 1 (step S56). After transmitting the communication start signal, the CPU 11 of the handy scanner 1 determines whether or not the connection (communication) is established between the handy scanner 1 and the mobile phone 2 (step S57).

If the connection is not established (NO in step S57), the CPU 11 repeats the above-mentioned process. On the other hand, if the CPU 11 receives the ACK signal from the mobile phone 2 and determines that the connection is established (YES in step S57), it transmits a model information request signal so as to obtain the model information of the currently connected mobile phone 2 (step S58). When the controller of the mobile phone 2 receives the model information request signal, it reads the model information stored in the memory (not shown) (step S59), and transmits the information to the handy scanner 1 (step S61). The handy scanner 1 obtains the transmitted model information, i.e., temporarily stores the model information in the RAM 12 (step S62).

The CPU 11 reads the model information stored in the RAM 12, and refers to the conversion table 151 to search for the conversion information corresponding to the model information (step S63). The CPU 11 determines whether or not the obtained model information is present, or whether or not the conversion information corresponding to the obtained model information is present, in the conversion table (step S64). If the model information is not present, or the conversion information corresponding to the model information is not present (NO in step S64), the CPU 11 causes the LED 14 to emit light (step S65), and causes a sound signal to be outputted from the speaker 141 (step S66). In another example, a pre-stored text in the storage unit 15 may be read and outputted to the mobile phone 2, and then displayed on the display section 24. For example, a text message such as “This mobile phone 2 is not valid for services . . . ” may be displayed.

Then, the process of obtaining the conversion information corresponding to the absent model information from the WWW server 3 is performed (step S67). Note that this process will be described later. Similarly, the process of obtaining a protocol corresponding to the absent model information is performed (step S68). Note that since the protocol obtaining process is substantially the same as the process of obtaining the conversion information (step S67), the detailed explanation thereof is omitted. Subsequently, the CPU 11 stores the obtained conversion information in the conversion table 151, and stores the obtained protocol in the protocol table 152 (step S69). In step S64, if the same model information as the obtained model information, or the conversion information corresponding to the model information, is preset (YES in step S64), the CPU 11 skips the processes of step S65 through step S69.

Thereafter, the CPU 11 reads the conversion information corresponding to the obtained model information from the conversion table 151 (step S610), and also reads the image data and information such as the image size from the image storage memory 120 (step S71). The CPU 11 converts the read image data, based on the conversion information (step S72). More specifically, the CPU 11 compares the read image size with the screen size in the conversion information, and enlarges/reduces the image. Moreover, conversion is performed for the number of colors and the image format, according to the processes similar to those of known image processing software.

Besides, the CPU 11 reads the protocol corresponding to the obtained model information (step S73), and performs the transmission of the image to the mobile phone 2, according to the read protocol. First, the CPU 11 transmits a transmission start signal for starting the transmission of the image to the mobile phone 2 (step S74). The mobile phone 2 receives this signal, and transmits an ACK signal to the handy scanner 1 (step S75). The CPU 11 of the handy scanner 1 receives the ACK signal, specifies the destination address, and transmits the converted image data to the mobile phone 2 in transmission timing according to the read protocol (step S76).

The mobile phone 2 stores the transmitted image data at the destination address (step S77). Then, the user of the mobile phone 2 sets the stored image data for the standby screen, etc. Since the present invention is constructed as described above, it is possible to display the image in a size and colors suitable for the display section 24 by simply scanning a picture, map, etc. in a magazine or the like and establishing a connection with an arbitrary mobile phone 2. Next, the following description will explain a sub-routine of step S67, i.e., the process to be performed to obtain the model information, conversion information and protocol which are not present in the handy scanner 1 because they are the information about a newly released model, or for other reasons.

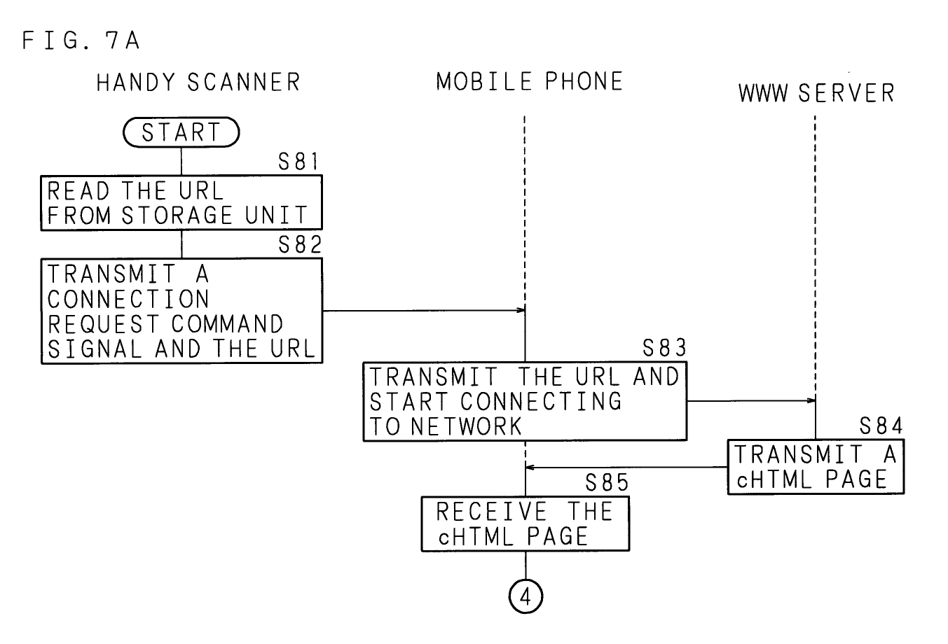

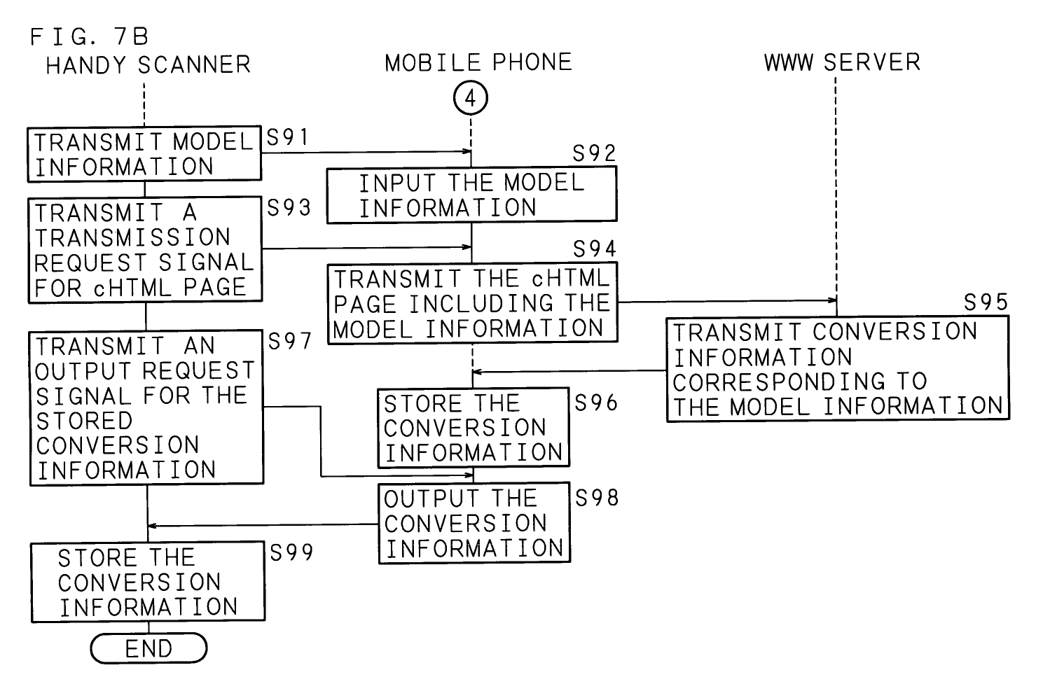

New model information, etc. are obtained by receiving distribution from the WWW server 3 through the mobile phone 2. The contents will be explained below with reference to the flow chart. FIGS. 7A and 7B are a flow chart showing the procedure for obtaining new model information, etc. First, the CPU 11 of the handy scanner 1 reads the URL that is the communication address of the WWW server 3 from the storage unit 15 (step S81). The CPU 11 transmits a connection request command signal for the Internet and the read URL to the mobile phone 2 (step S82). The connection request command signal is specifically a command to activate the browser of the mobile phone 2. After activating the browser of the mobile phone 2 according to the browser activation command, an ACK signal is transmitted to the handy scanner 1, and then the URL is transmitted from the handy scanner 1 to the mobile phone 2. Note that this URL is pre-stored in the storage unit 15.

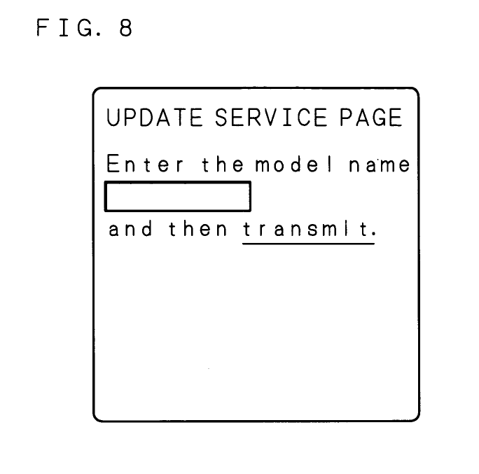

After activating the browser, the mobile phone 2 transmits the URL and starts connecting to the WWW server 3 (step S83). The WWW server 3 reads the cHTML (compact Hyper Text Markup Language) page and transmits it to the mobile phone 2 (step S84). The mobile phone 2 receives the transmitted cHTML page (step S85), and then the browser analyzes its contents and displays them on the display section 24. FIG. 8 is an explanatory view showing a screen image displayed on the display section 24. As shown in FIG. 8, a box for entering the model name and the transmission button are displayed.

Here, when the user presses the scanning/transmission start button 132, the CPU 11 transmits the model information obtained in S62 to the mobile phone 2 (step S91). The mobile phone 2 inputs the transmitted model information (step S92). Thereafter, when the user presses the scanning/transmission start button 132, the CPU 11 transmits a transmission request signal for the cHTML page to the mobile phone 2 (step S93). The mobile phone 2 receives the transmission request signal for the cHTML page and then transmits the cHTML page including the model information to the WWW server 3 (step S94). Note that the user may perform the entry of the model name and the pressing of the transmission button through the push buttons of the mobile phone.

The WWW server 3 reads the conversion information corresponding to the transmitted model information and transmits it to the mobile phone 2 (step S95). More specifically, the WWW server 3 activates a CGI (Common Gateway Interface) program, creates an SQL (Structured Query Language) using the model information as a key, and talks to a database server (not shown) in the SQL to search for the conversion information corresponding to the model information. Then, the searched conversion information is transmitted to the mobile phone 2. Note that, in the database server (not shown), the latest information, such as conversion information and protocols, of a variety of manufacturers are stored. The mobile phone 2 stores the transmitted conversion information (step S96). When the conversion information is received, cHTML such as “The download is complete.” is displayed on the display section 24 of the mobile phone 2.

Then, when the user presses the scanning/transmission start button 132, the CPU 11 transmits an output request signal for the stored conversion information to the mobile phone 2 (step S97). According to the output request signal, the mobile phone 2 reads the conversion information and outputs it to the handy scanner 1 (step S98). Finally, the CPU 11 stores the transmitted conversion information in the conversion table 151, in association with the model information obtained beforehand (step S99). Note that although the process of obtaining conversion information has been explained in detail, the process of obtaining a protocol is similar to this process and therefore the detailed explanation is omitted. As described above, if the model information, etc. are not present in the conversion table, new information is obtained from the WW server 3. Hence, even when a new mobile phone 2 is released, it is possible to appropriately display the captured image according to this new mobile phone 2.

Second Embodiment

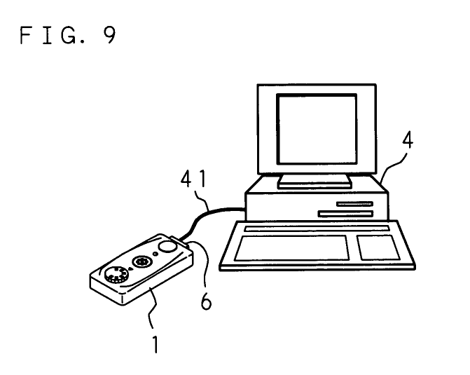

FIG. 9 is a schematic view showing the outline of the handy scanner 1, etc. of the second embodiment. The handy scanner 1 is connected to a personal computer 4 in a shop or owned by a user with a USB (Universal Serial Bus) cable 41 or the like. In the database (not shown) of the personal computer 4, the latest information including the model information, conversion information and protocol is updated through a network such as the Internet.

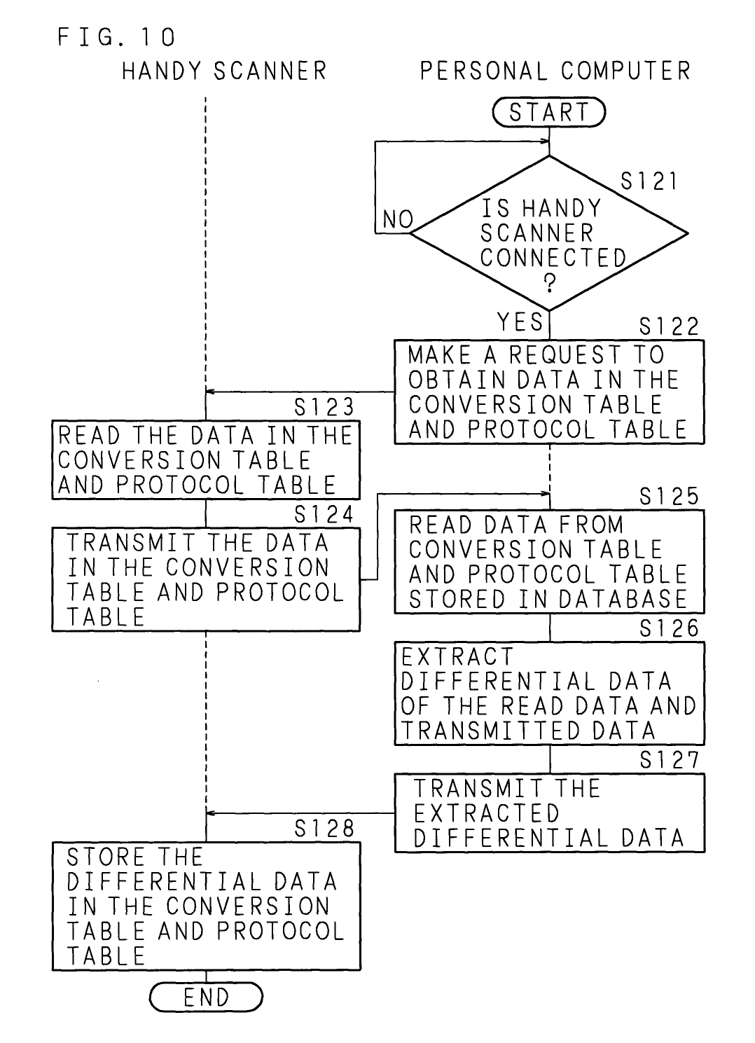

FIG. 10 is a flow chart showing the procedure for obtaining new model information, etc. The personal computer 4 determines whether or not the handy scanner 1 is connected with the USB cable 41 (step S121). If the handy scanner 1 is not connected (NO in step S121), the personal computer 4 repeats the above-mentioned process until the handy scanner 1 is connected. On the other hand, if the connection of the handy scanner 1 is recognized (YES in step S121), the personal computer 4 requests the handy scanner 1 to obtain the data in the conversion table 151 and protocol table 152 (step S122).

In order to reply to the request for the data, the CPU 11 of the handy scanner 1 reads the data stored in the conversion table 151 and protocol table 152 (step S123), and transmits the table data to the personal computer 4 (step S124). The personal computer 4 stores the transmitted data about the handy scanner 1 temporarily, and reads data from the conversion table and protocol table in its own database (step S125). The personal computer 4 compares the data stored in the memory with the read data so as to extract the differential data (step S126).

The extracted differential data is transmitted to the handy scanner 1 (step S127). The CPU 11 of the handy scanner 1 stores the differential data in the conversion table 151 and the protocol table 152 (step S128).

When there is no information about new model, it is possible to easily upload the latest information in a shop, etc. Then, even when a new mobile phone 2 is released, it is possible to appropriately display the captured image according to this new mobile phone 2. Note that, in the second embodiment, although necessary information is downloaded by connecting to the personal computer 4 with the USB cable 41, the present invention is not necessarily limited to this, and the necessary information may be downloaded by installing a modem in the handy scanner 1 and directly accessing the WWW server 3.

The second embodiment has the above-described structures. Since other structures and functions are the same as those of the first embodiment, the corresponding parts are designated with the same reference numbers and the detailed explanation thereof is omitted.

Third Embodiment

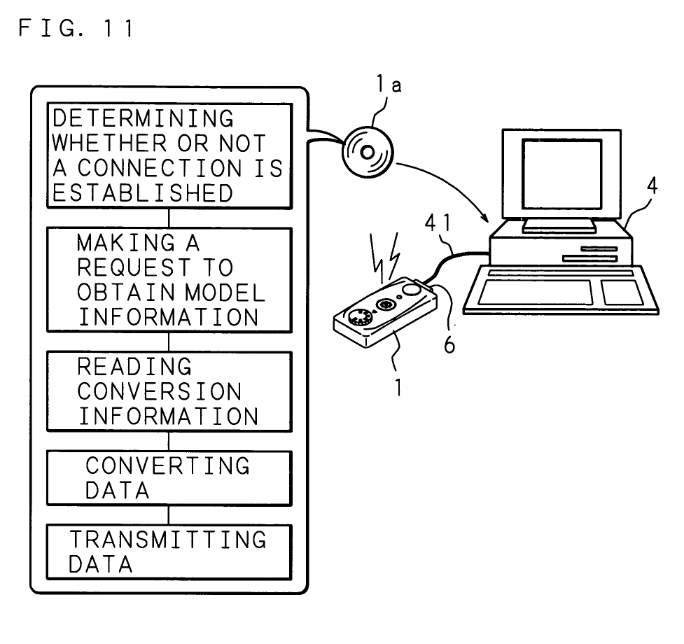

FIG. 11 is a schematic view showing the outline of the handy scanner 1, etc. of the third embodiment. A computer program for operating the handy scanner 1 according to the above-described first and second embodiments can be provided by a removable memory product, such as a CD-ROM and an MO, through the personal computer 4 as in the third embodiment. Moreover, it is also possible to provide the computer program by propagating it as a carrier wave via a network. The contents will be explained below.

By inserting into a memory product reader (not shown) of the personal computer 4 shown in FIG. 11 a memory product 1a (such as a CD-ROM, MO, or DVD-ROM) storing a program to cause a computer to determine whether or not a connection is established, make a request for the model information, read the conversion information, convert the data and transmit the data, this program is installed in the storage unit 15 of the handy scanner 1 through the USB cable 41. Alternatively, the program may be downloaded from an external computer through the modem (not shown) of the handy scanner 1 and installed in the storage unit 15. This program is loaded in the RAM 12 of the handy scanner 1 and executed. Accordingly, the program functions as the handy scanner 1 of the present invention as described above.

The third embodiment has the above-described structures. Since other structures and functions are the same as those of the first and second embodiments, the corresponding parts are designated with the same reference numbers and the detailed explanation thereof is omitted.

As described in detail above, the present invention determines whether or not a connection is established between the communication section of the image transmitter and a mobile phone, and transmits a request command to obtain the model information of the mobile phone to the mobile phone if it is determined that the connection is established. When the mobile phone receives this request command, it reads the model information from the internal memory and transmits the model information to the image transmitter. When the image transmitter obtains the model information according to the request for the model information, it refers to the conversion table and reads the conversion information corresponding to the obtained model information. Then, the image transmitter converts the image data stored in the storage unit, based on the read conversion information, and transmits the converted image data to the mobile phone through the communication section. It is therefore possible to easily transmit the image data without requiring the user to enter the model information of his/her mobile phone. Moreover, since the display screen for selection can be omitted if necessary, it is possible to provide a low-cost image transmitter. In other words, it is often the case that general users do not correctly remember the model names of mobile phones they purchased and the model names of mobile phones of third parties, but the present invention allows capturing of images by simple capturing and connecting operations.

Furthermore, in the present invention, if the obtained model information or the conversion information corresponding to the model information is not present in the conversion table, the conversion information corresponding to the model information is obtained from external sources. Thus, even when a new model is released, it is possible to transmit appropriate image data to the new mobile phone without making the image transmitter out of date.

Besides, the present invention prepares a protocol table storing a protocol for a transmission of image data between the communication section and mobile phone, in association with each model information. When transmitting image data, a protocol corresponding to the obtained model information is read from the protocol table, and then the image data converted according to the read protocol is transmitted to the mobile phone through the communication section. Thus, the present invention can produce advantageous effects, such as enabling image data to be transmitted appropriately to various types of mobile phones.

As this invention may be embodied in several forms without departing from the spirit of essential characteristics thereof, the present embodiments are therefore illustrative and not restrictive, since the scope of the invention is defined by the appended claims rather than by the description preceding them, and all changes that fall within metes and bounds of the claims, or equivalence of such metes and bounds thereof are therefore intended to be embraced by the claims.

1. An image transmitting method for storing image data captured by an image capturing unit of an image transmitter in a storage unit, reading the stored image data and transmitting the read image data from a communication section to a mobile phone having a display section of the image transmitter, comprising the steps of:
determining whether or not a connection is established between the communication section and the mobile phone;
requesting the mobile phone to obtain model information of the mobile phone if it is determined that the connection is established;
when the model information is obtained from the mobile phone in response to the request for the model information, reading conversion information corresponding to the obtained model information with reference to a conversion table that stores conversion information, which is used to convert captured image data into image data according to model characteristics, in association with each model information;
converting the image data stored in the storage unit, based on the read conversion information; and
transmitting the converted image data to the mobile phone through the communication section.

2. An image transmitter comprising:
an image capturing unit for capturing image data;
a storage unit for storing the captured image data;
a communication section for transmitting the image data stored in the storage unit to a mobile phone having a display section; and
a processor capable of performing the operation comprising the steps of
determining whether or not a connection is established between the communication section and the mobile phone;
requesting the mobile phone to obtain model information of the mobile phone if it is determined that the connection is established;
when the model information is obtained from the mobile phone according to the request for the model information, reading conversion information corresponding to the obtained model information with reference to a conversion table that stores conversion information, which is used to convert captured image data into image data according to model characteristics, in association with each model information;
converting the image data stored in the storage unit, based on the read conversion information; and
transmitting the converted image data to the mobile phone through the communication section.

3. The image transmitter of claim 2,
wherein the processor is further capable of performing the operation comprising the steps of:
obtaining conversion information corresponding to the obtained model information from external sources, if the obtained model information or conversion information corresponding to the model information is not present in the conversion table; and
storing the conversion information corresponding to the model information obtained in the obtaining step in the conversion table.

4. The image transmitter of claim 2, wherein the processor is further capable of performing the operation comprising the steps of:
storing a communication address of a server computer which is connected to the mobile phone through a network and stores the conversion information corresponding to model information;
outputting a connection request command for the server computer, the stored communication address and the obtained model information to the mobile phone, if the obtained model information or conversion information corresponding to the model information is not present in the conversion table;
requesting the mobile phone to obtain the conversion information corresponding to the model information of the mobile phone, which is distributed to the mobile phone from the server computer; and
storing the obtained conversion information corresponding to the mobile phone in the conversion table in association with the model information.

5. The image transmitter of claim 3,
wherein the processor is further capable of performing the operation comprising the step of providing information indicating absence of corresponding conversion information, if the obtained model information or conversion information corresponding to the model information is not present in the conversion table.

6. The image transmitter of claim 4,
wherein the processor is further capable of performing the operation comprising the step of providing information indicating absence of corresponding conversion information, if the obtained model information or conversion information corresponding to the model information is not present in the conversion table.

7. The image transmitter of claim 2, further comprising a protocol table storing a protocol for a transmission of image data between the communication section and mobile phone, in association with each model information,
wherein the transmitting step comprises reading a protocol corresponding to the obtained model information from the protocol table, and transmitting the image data converted according to the read protocol to the mobile phone through the communication section.

8. The image transmitter of claim 3, further comprising a protocol table storing a protocol for a transmission of image data between the communication section and mobile phone, in association with each model information,
wherein the transmitting step comprises reading a protocol corresponding to the obtained model information from the protocol table, and transmitting the image data converted according to the read protocol to the mobile phone through the communication section.

9. The image transmitter of claim 4, further comprising a protocol table storing a protocol for a transmission of image data between the communication section and mobile phone, in association with each model information,
wherein the transmitting step comprises reading a protocol corresponding to the obtained model information from the protocol table, and transmitting the image data converted according to the read protocol to the mobile phone through the communication section.

10. The image transmitter of claim 5, further comprising a protocol table storing a protocol for a transmission of image data between the communication section and mobile phone, in association with each model information,
wherein the transmitting step comprises reading a protocol corresponding to the obtained model information from the protocol table, and transmitting the image data converted according to the read protocol to the mobile phone through the communication section.

11. An image transmitter comprising:
an image capturing unit for capturing image data;
a storage unit for storing the captured image data;
a communication section for transmitting the image data stored in the storage unit to a mobile phone having a display section;
means for determining whether or not a connection is established between the communication section and the mobile phone;
means for requesting the mobile phone to obtain model information of the mobile phone if it is determined that the connection is established;
when the model information is obtained from the mobile phone in response to the request for the model information, means for reading conversion information corresponding to the obtained model information with reference to a conversion table that stores conversion information, which is used to convert captured image data into image data according to model characteristics, in association with each model information;
means for converting the image data stored in the storage unit, based on the read conversion information; and
means for transmitting the converted image data to the mobile phone through the communication section.

12. The image transmitter of claim 11, further comprising:
means for obtaining conversion information corresponding to the obtained model information from external sources, if the obtained model information or conversion information corresponding to the model information is not present in the conversion table; and
means for storing the conversion information corresponding to the model information obtained by the obtaining means in the conversion table.

13. The image transmitter of claim 11, further comprising:
means for storing a communication address of a server computer which is connected to the mobile phone through a network and stores the conversion information corresponding to model information;
means for outputting a connection request command for the server computer, the stored communication address and the obtained model information to the mobile phone, if the obtained model information or conversion information corresponding to the model information is not present in the conversion table;
means for requesting the mobile phone to obtain the conversion information corresponding to the model information of the mobile phone, which is distributed to the mobile phone from the server computer; and
means for storing the obtained conversion information corresponding to the mobile phone in the conversion table in association with the model information.

14. The image transmitter of claim 12, further comprising means for providing information indicating absence of corresponding conversion information, if the obtained model information or conversion information corresponding to the model information is not present in the conversion table.

15. The image transmitter of claim 11, further comprising a protocol table storing a protocol for a transmission of image data between the communication section and mobile phone, in association with each model information,
wherein said transmitting means is designed to read a protocol corresponding to the obtained model information from the protocol table and transmit the image data converted according to the read protocol to the mobile phone through the communication section.

16. A memory product storing a computer program for storing image data captured by an image capturing unit of an image transmitter in a storage unit, reading the stored image data and transmitting the read image data from a communication section of the image transmitter to a mobile phone having a display section, said computer program comprising the steps of:
causing a computer to determine whether or not a connection is established between the communication section and the mobile phone;
causing the computer to request the mobile phone to obtain model information of the mobile phone if it is determined that the connection is established;
when the model information is obtained from the mobile phone in response to the request for the model information, causing the computer to read conversion information corresponding to the obtained model information with reference to a conversion table that stores conversion information, which is used to convert captured image data into image data according to model characteristics, in association with each model information;
causing the computer to convert the image data stored in the storage unit, based on the read conversion information; and
causing the computer to transmit the converted image data to the mobile phone through the communication section.
